(19) United States
(12) Patent Application Publication
(10) Pub. No.: US 2015/0102829 A1
(43) Pub. Date: Apr. 16, 2015

(54) FINGERPRINT SENSOR PACKAGE AND METHOD FOR MANUFACTURING SAME

(71) Applicant: CRUCIALTEC CO., LTD., Asan-si, Chungchengnam-do (KR)

(72) Inventors: Dong Nam Son, Busan (KR); Young Moon Park, Cheonan-si (KR); Ki Don Kim, Asan-si (KR)

(73) Assignee: CRUCIALTEC CO., LTD, Asan-si, Chungchengnam-do (KR)

(21) Appl. No.: 14/401,116

(22) PCT Filed: May 14, 2013
(86) PCT No.: PCT/KR2013/004174

§ 371 Date: Nov. 14, 2014

(30) Foreign Application Priority Data
May 15, 2012 (KR) 10-2012-0051486

(51) Int. Cl. G06K 9/00; H01L 21/56

(52) U.S. Cl. CPC G06K 9/0002; H01L 21/56
USPC 324/692; 438/48

(57) ABSTRACT

The objective of the present invention is to provide a fingerprint sensor package having a novel structure and a method for manufacturing same, the fingerprint sensor package enabled with obtaining an accurate fingerprint image by minimizing the distance between a top surface of a sensing portion in a fingerprint sensor and a fingerprint, so as to improve mechanical strength and tolerance to electrostatic discharge compared to existing fingerprint sensor packages. To this end, the present invention provides the fingerprint sensor package and the method for manufacturing same, the fingerprint sensor package comprising: the fingerprint sensor comprising a sensing portion on which pixels for detecting fingerprint data are arranged in an array; via frame being arranged around and spaced apart from the fingerprint sensor and comprising via; a connection electrode for electrically connecting a bonding pad, which is provided on an upper surface of the fingerprint sensor for external access, and the via hole on the via frames; a conductive pattern compring a driving electrode for generating a driving signal for the fingerprint sensor; a mold body which is formed so that the fingerprint sensor and the via frame are integrated; and a protective layer for covering the upper surface of the fingerprint sensor.

### TECHNICAL FIELD

The present invention relates to a fingerprint sensor package, and more particularly to a package structure for a fingerprint sensor used in recognizing a fingerprint and a method of manufacturing the same.

### BACKGROUND ART

Fingerprint recognition technology is generally used to prevent a security accident through user registration and authentication procedures, and is applied to networking defense for individuals and a group, protection for contents and data, safe access control for a computer, a mobile device or the like, etc.

With recent development of mobile technology, the fingerprint recognition technology has been widespread. For example, image data of a fingerprint may be used for a pointing device that controls a mouse pointer.

For the fingerprint recognition technology, a fingerprint sensor has been used. The fingerprint sensor is a device for recognizing a pattern of a fingerprint from a finger of a human. The fingerprint sensor is classified into an optical sensor, an electric sensor, an ultrasonic sensor, and a thermal sensor in accordance with sensing types. Each of these fingerprint sensors obtains image data of a fingerprint from a finger by its own driving type.

Like a general semiconductor chip, such a fingerprint sensor is also sealed up with a resin material such as an epoxy molding compound (EMC), etc. Thus, the fingerprint sensor is mounted as a fingerprint sensor package to a main board of an electronic device.

A distance between a top surface of a sensing portion in the fingerprint sensor and a fingerprint has to be as short as possible, so that the fingerprint sensor package can accurately obtain the image data of the fingerprint.

In addition, if sensitivity to obtain the fingerprint data becomes higher, a protective coating layer to the sensing portion in the fingerprint sensor can be thicker than that of the existing fingerprint sensor, thereby improving the mechanical strength of the fingerprint sensor package and tolerance to electrostatic discharge or the like.

Further, if the sensitivity of the fingerprint sensor to obtain the fingerprint data becomes higher, it is possible to improve the quality of image data as compared with that of the existing fingerprint sensor under the condition that the same number of pixels is given per unit area, and it is also possible to decrease the number of pixels and thus reduce the size of the fingerprint sensor package as compared with that of the existing fingerprint sensor under the condition that image data is desired to have the same quality as that of the existing fingerprint sensor.

Accordingly, there is a need of developing a fingerprint sensor package having a novel structure capable of improving sensitivity of a fingerprint sensor.

### DISCLOSURE

### Technical Problem

The present invention is conceived to solve the foregoing problems of the conventional blood pressure monitor, and it is an aspect of the present invention to provide a fingerprint sensor package having a novel structure capable of accurately obtaining fingerprint image data by minimizing a distance between a top surface of a sensing portion in a fingerprint sensor and a fingerprint, thereby improving mechanical strength and tolerance to electrostatic discharge as compared with the existing fingerprint sensor packages, and a method for manufacturing the same.

### Technical Solution

In accordance with one aspect of the present invention, a fingerprint sensor package includes a fingerprint sensor provided with a sensing portion on which pixels for detecting fingerprint data are arranged in an array; via frames which are arranged around and spaced apart from the fingerprint sensor and include via holes; a conductive pattern including a connection electrode by which a bonding pad provided on an upper surface of the fingerprint sensor and used for external access and the via hole of the via frame are electrically connected, and a driving electrode which generates a driving signal for the fingerprint sensor; a mold body in which the fingerprint sensor and the via frame are integrated; and a protective layer formed to cover the upper surface of the fingerprint sensor.

In accordance with one aspect of the present invention, a method of manufacturing a fingerprint sensor package includes: preparing a via frame including conductive via holes and a hollow; molding a die and the via frame to be integrated by a mold resin in a state that the die is placed in the hollow of the via frame; forming a first protective layer on an entire area on a side, in which a bonding pad is formed, of a structure including the molded die; selectively removing a predetermined area of the first protective layer; forming a conductive patter which includes a connection electrode for connecting the bonding pad and the via hole of the die on the first protective layer, and a driving electrode for generating a driving signal for a fingerprint sensor; forming a second protective layer on an entire area of an upper surface in a structure including the conductive pattern; and forming a coating layer having black, white or another color on the second protective layer.

In accordance with one aspect of the present invention, a method of manufacturing a fingerprint sensor package includes preparing a via frame including conductive via holes and a hollow; attaching a molding tape for die attach and die molding to cover the hollow of the via frame; attaching a die to a center portion of the molding tape so that a bonding pad of the die can face the molding tape; molding the die and the via frame to be integrated by an epoxy molding compound (EMC); removing the molding tape; forming a first protective layer on an upper surface, from which the molding tape is removed, of a structure including the molded die, without forming the first protective layer in an area above the via hole and an area corresponding to the bonding pad; forming a connection electrode for connecting the bonding pad and the via hole of the die on the first protective layer, and a driving electrode for generating a driving signal for a fingerprint sensor; forming a second protective layer on an entire area of an upper surface in a structure including the conductive pattern; and forming a coating layer having black, white or another color on the second protective layer.

### Advantageous Effects

A fingerprint sensor package according to the present invention, and a method of manufacturing the same have the following effects.

First, according to an embodiment of the present invention, it is possible to make the fingerprint sensor package be ultra slim. That is, the present invention is effective to make an ultra slim fingerprint sensor package since a problem of a molding height due to a wire loop is solved.

Further, according to an embodiment of the present invention, a distance between a top surface of a sensing portion in a fingerprint sensor and a fingerprint is minimized, thereby more clearly and accurately obtaining fingerprint image data. Thus, a coating thickness is sufficiently secured, and therefore mechanical strength and tolerance to electrostatic discharge are improved as compared with the existing fingerprint sensor package.

In addition, the fingerprint sensor has no difference in height between the sensing portion of the fingerprint sensor and the molding resin around the sensing portion since the problem of the molding height due to the wire loop is solved, thereby having an effect on allowing a finger to more freely move for fingerprint recognition.

Furthermore, the ultra slim fingerprint sensor package according to an embodiment of the present invention can be manufactured by not an individual packaging method but a wafer-level packaging method.

That is, previously prepared fingerprint sensors are respectively arranged in hollows of via frames having an area large enough to manufacture a plurality of packages; individually undergo a molding process, a process of forming a conductive pattern, a packaging process of forming a protective layer, etc.; and then singularized into respective packages. Accordingly, productivity is improved in manufacturing the fingerprint sensor.

### DESCRIPTION OF DRAWINGS

The above and/or other aspects will become apparent and more readily appreciated from the following description of exemplary embodiments, taken in conjunction with the accompanying drawings, in which:

FIG. 1 is a sectional view of a fingerprint sensor package according to an embodiment of the present invention;

FIG. 2 is a cross-sectional view taken along line A-A′ in FIG. 1;

FIG. 3 shows top and bottom views of FIG. 1;

FIGS. 4a and 4b show processes of manufacturing the fingerprint sensor package according to an embodiment of the present invention, in which FIG. 4a includes

(a) shows that a via frame is prepared,

(b) shows that a molding tape for die attach and die molding is attached to the via frame,

(c) shows that a die is mounted to the molding tape,

(d) shows that the die is molded with a molding resin (EMC), and

(e) shows that the molding tape is removed by overturning the whole molded die after molding,

FIG. 4b includes

(f) shows that a first protective layer is formed by an upper surface including the die,

(g) shows that a conductive pattern is formed,

(h) shows that a second protective layer is formed,

(i) shows that black coating is performed on the second protective layer, and

(j) shows that a solder land for mounting to a main board is exposed through laser drilling;

FIG. 5 shows a fingerprint sensor package according to another embodiment of the present invention, which corresponds to the cross-sectional view of FIG. 2;

FIG. 6 is a sectional view of a fingerprint sensor package according to still another embodiment of the present invention; and

FIG. 7 shows top and bottom views of FIG. 6.

### BEST MODE

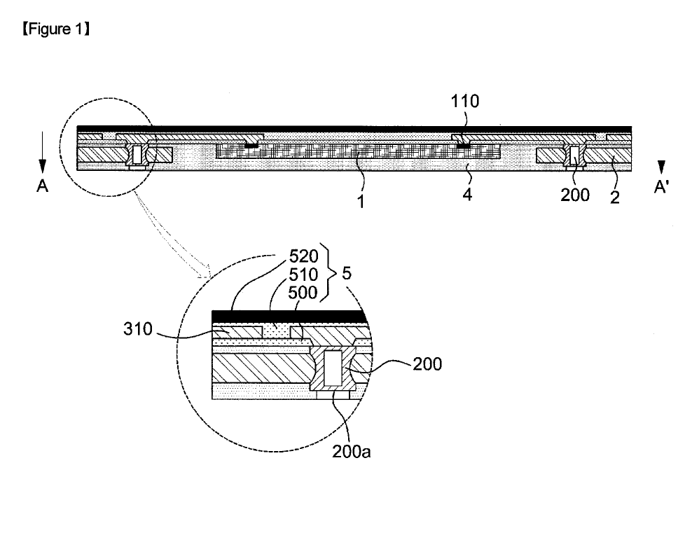

Hereinafter, exemplary embodiments of a fingerprint sensor package according to the present invention and a method of manufacturing the same will be described in detail with reference to FIGS. 1 to 7.

### Embodiment 1

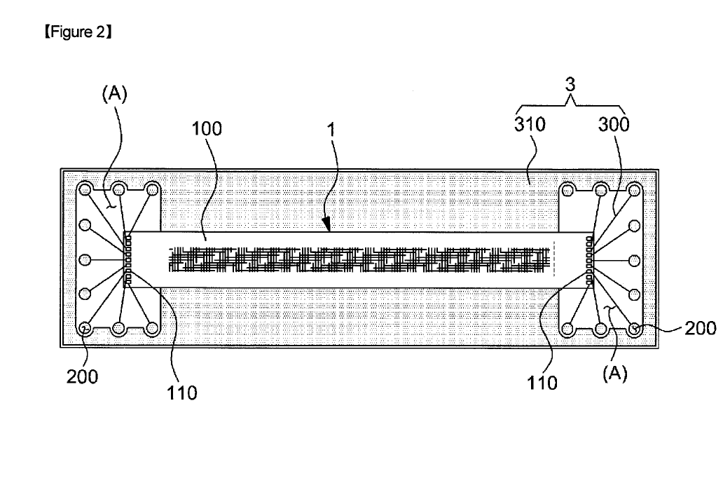

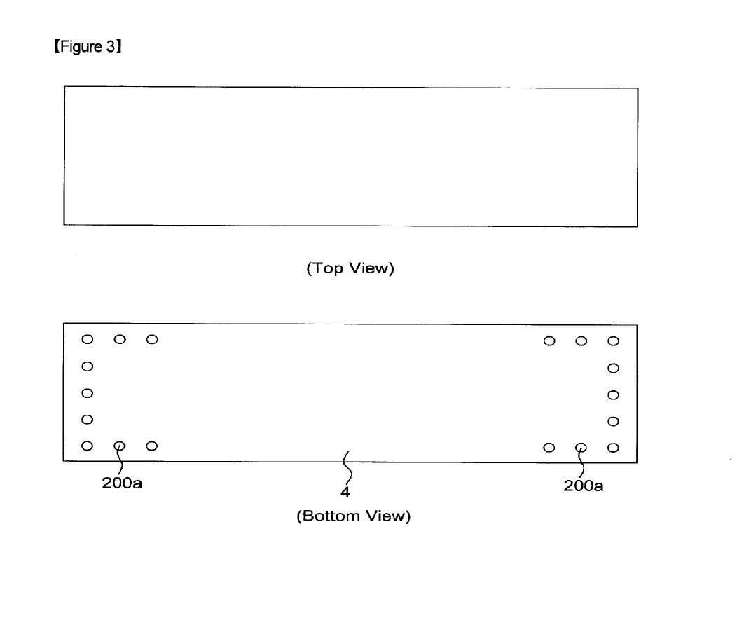

FIG. 1 is a sectional view of a fingerprint sensor package according to an embodiment of the present invention, FIG. 2 is a cross-sectional view taken along line A-A′ in FIG. 1, and FIG. 3 shows top and bottom views of FIG. 1.

As shown therein, the fingerprint sensor package according to an embodiment of the present invention includes a fingerprint sensor 1 provided with a sensing portion 100 on which pixels for detecting fingerprint data are arranged in an array; via frames 2 which are arranged around and spaced apart from the fingerprint sensor 1 and include via holes 200; a conductive pattern 3 including a connection electrode 300 by which a bonding pad 110 provided on an upper surface of the fingerprint sensor 1 and used for external access and the via hole 200 of the via frame 2 are electrically connected, and a driving electrode 310 which generates a driving signal for the fingerprint sensor 1; a mold body 4 in which the fingerprint sensor 1 and the via frame 2 are integrated; and a protective layer 5 formed to cover the upper surface of the fingerprint sensor 1.

The driving electrode 310 emits a driving signal to a medium such as a finger. The driving signal is an electric signal including a radio frequency (RF) signal, and makes difference in electric characteristics between peaks and valleys of a fingerprint. For example, the driving signal makes difference in capacitance caused by difference in height between the peaks and valleys of the fingerprint.

The connection electrode 300 and the driving electrode 310, which constitute the conductive pattern 3, are insulated from each other.

In addition, a solder land 200a is exposed to the outside of the mold body 4 at an opposite side to a portion of the via hole 200 of the via frame 2, to be electrically connected to the bonding pad 110 of the fingerprint sensor 1 by the connection electrode 300 (that is, to a connection portion on the upper surface of the fingerprint sensor 1). In other words, a bottom side of the via hole 200 is not covered with the mold body 4 but exposed to the outside so as to be easily mounted to a main board (not shown).

Further, the protective layer 5 includes a first protective layer 500 formed as an insulation layer on the entire upper surface except the conductive pattern 3, a second protective layer 510 formed as an insulation layer on the entire upper surface covering the first protective layer 500 and the conductive pattern 3, and a black coating layer 520 formed on the entire upper surface of the second protective layer 510.

In this embodiment, the second protective layer 510 is coated with the black coating layer 520, but not limited thereto. Alternatively, a white coating layer or other color coating layers suitable for specifications of a product, to which the fingerprint sensor package is applied, may be used. Similarly, this is applied to the following embodiments.

In FIG. 2, the conductive pattern unformed area (A) refers to an insulation area except the connection electrode 300 by which the via hole 200 and the bonding pad 110 are connected.

The fingerprint sensor 1 generates an image or its template based on the foregoing difference in electrical characteristics. The generated fingerprint image or template may not only identify and authenticate a fingerprint but also track motion of a finger.

In this specification, devices for identifying and authenticating a fingerprint and tracking the motion of the fingerprint for navigation will be collectively called the “fingerprint sensor”.

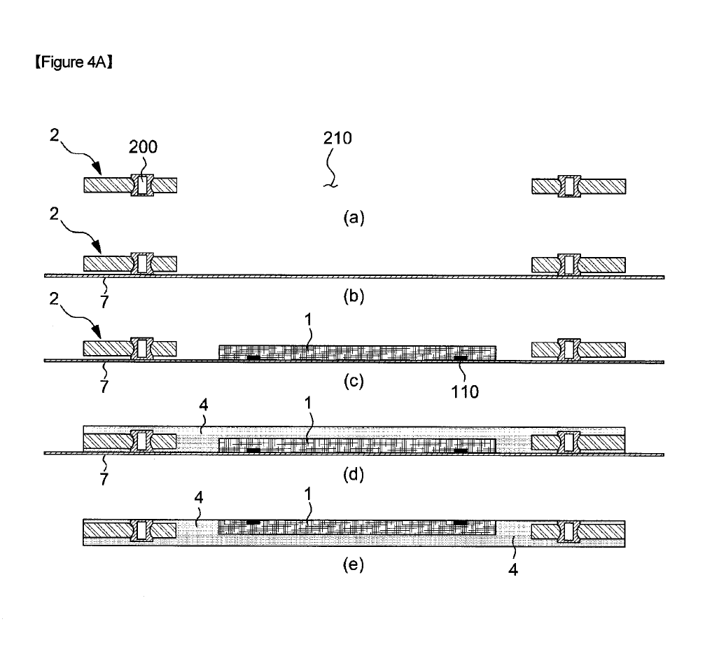

With this configuration, a process of manufacturing a fingerprint sensor package according to an embodiment of the present invention will be described with reference to (a) to (j) shown in FIGS. 4a and 4b.

First, the via frames 2 are prepared. The via frame 2 is a kind of substrate formed with a conductive via hole 200, and forms a hollow 210 (see (a) of FIG. 4a).

Next, a molding tape 7 is attached to the via frame 2 so as to cover the hollow 210 of the via frame 2 (see (b) of FIG. 4a). The molding tape 7 is provided for die attach and die molding.

Then, a die (i.e. the fingerprint sensor 1) is attached to the center of the molding tape 7 (see (c) of FIG. 4a). The die 1 is attached to the molding tape 7 so that the bonding pad 110 can face the molding tape 7.

After the die is completely attached, the die 1 attached to the molding tape 7 and the via frame 2 are molded with a mold resin (e.g., epoxy molding compound (EMC)) so that they can be integrated with each other (see (d) of FIG. 4a). The molding tape 7 may be placed at a lower side and forms a bottom surface.

After the die is completely molded, the molding tape 7 is removed, and the molded die is overturned so that the bonding pad 110 can face upward (see (e) of FIG. 4a). Alternatively, the molding tape 7 may be removed in the state that the molded die is turned upside down to make the bonding pad 110 face upward.

Then, the first protective layer 500 is formed on the upper surface of the structure having the molded die (see (f) of FIG. 4b). The first protective layer 500 may be made of polymer, polyamide, or the like material.

Taking the following process of forming the conductive pattern into account, an area above the via hole and an area corresponding to the bonding pad are masked so as not to form the protective layer thereon.

After the first protective layer 500 is selectively removed, the conductive pattern 3 is formed on the first protective layer 500 (see (g) of FIG. 4b).

The conductive pattern 3 includes the connection electrode 300 to connect the bonding pad 110 of the die 1 and the via hole 200, and the driving electrode 310 to generate a driving signal for the fingerprint sensor. To this end, a metal thin film is formed on the first protective layer 500 and then patterned by selective etching or the like so that the conductive pattern 3 can have the connection electrode 300 and the driving electrode 310.

After the conductive pattern 3 is formed, the second protective layer 510 is formed with regard to the entire upper surface of the package (see (h) of FIG. 4b). Like the first protective layer, the second protective layer 510 is made of polymer, polyamide, or the like material.

Next, the black coating layer 520 is formed on the second protective layer 510 (see (i) of FIG. 4b). In this embodiment, black coating is performed, but not limited thereto. Alternatively, white coating or other color coating suitable for a product may be performed. The black, white and other color collating layers not only make the fingerprint sensor package be easily distinguishable from other products, but also reinforce the mechanical strength and durability of the fingerprint sensor package.

After the black coating is completed, the solder land 200a for mounting to the main board is exposed from the mold resin through laser drilling (see (j) of FIG. 4b).

The fingerprint sensor package completed by the foregoing processes is mounted to the main board of an electric and electronic product such as a mobile device and a computer, and performs its function.

### Embodiment 2

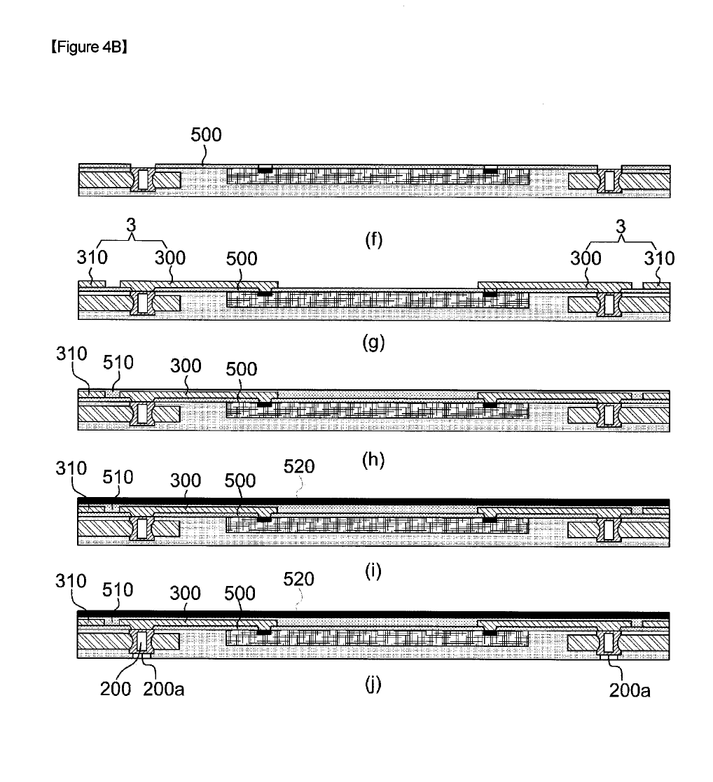

FIG. 5 shows a fingerprint sensor package according to another embodiment of the present invention, which corresponds to the cross-sectional view of FIG. 2.

Basic elements of the fingerprint sensor package according to this embodiment are the same as those of the foregoing [Embodiment 1] except a structure in an outward area around the vial holes 200 of the via frame 2.

According to this embodiment, the fingerprint sensor package includes a plurality of compensation holes 6 in an outward area around the via holes 200 of the via frame 2 in order to prevent the fingerprint sensor package from warpage due to difference in a coefficient of thermal expansion between the mold resin for integrating the die 1 with the via frame 2 and the conductive pattern 3 formed on the upper surface of the via frame.

For example, the compensation holes 6 are formed in a matrix on the compensation hole forming area (B) of FIG. 5.

The fingerprint sensor package with this configuration according to this embodiment is manufactured by basically the same processes as those of the foregoing [Embodiment 1] except an additional process of forming the compensation holes 6 in an outward area around the via holes 200.

In addition, the process of forming the compensation hole 6 may be performed after the process of forming the conductive pattern shown in (g) of FIG. 4b is completed. The compensation holes 6 minimize a contact area between the mold resin and the conductive pattern 3 formed on the upper surface of the via frame 2, and thus effectively prevent the fingerprint sensor package from warpage due to the difference in the coefficient of thermal expansion when the fingerprint sensor package operates.

### Embodiment 3

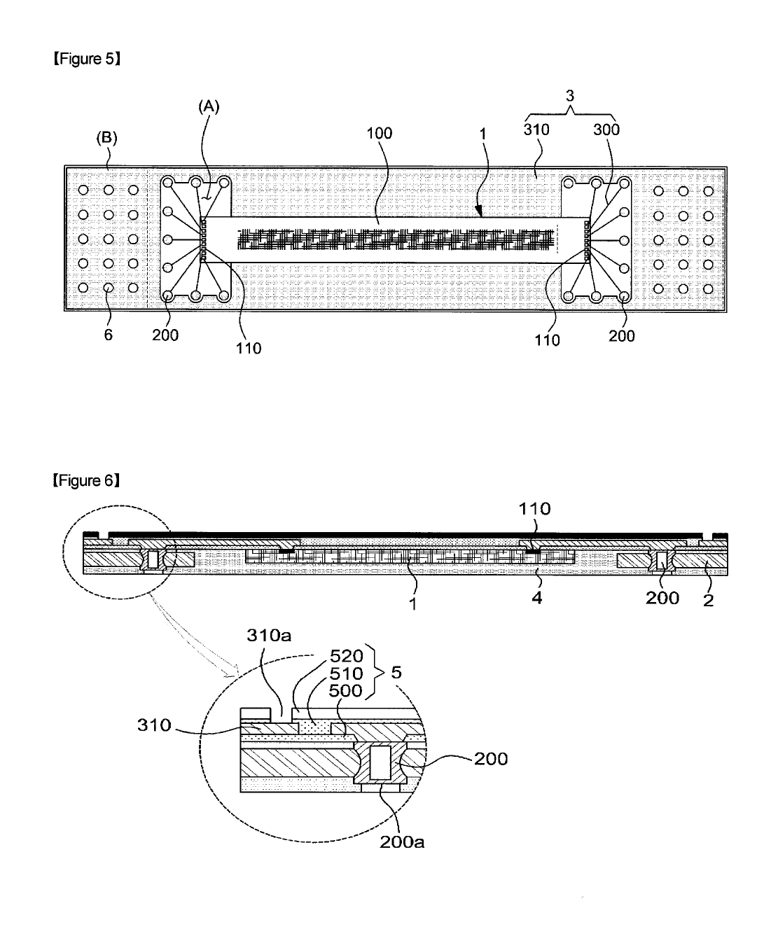

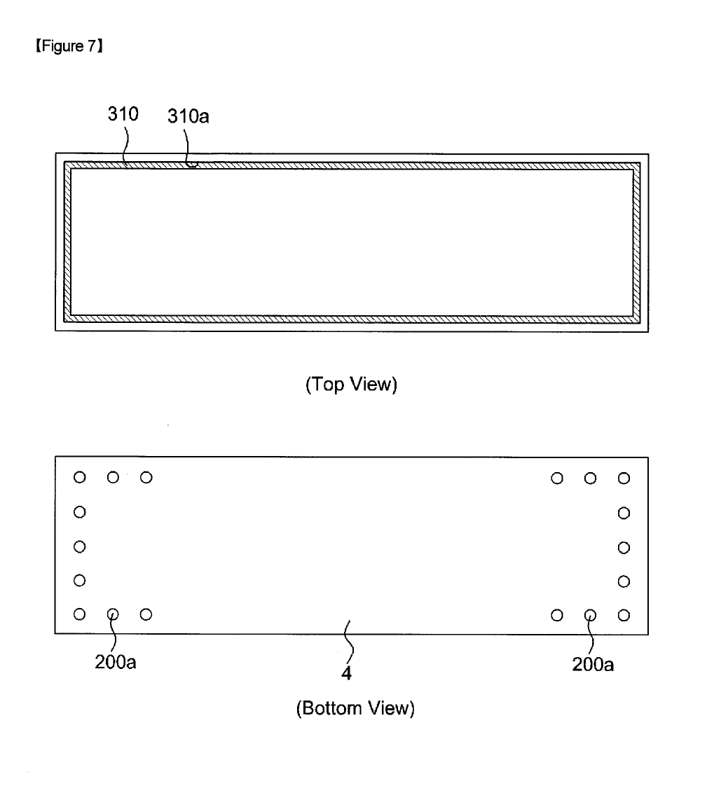

FIG. 6 is a sectional view of a fingerprint sensor package according to still another embodiment of the present invention, and FIG. 7 shows top and bottom views of FIG. 6.

Basic elements of the fingerprint sensor package according to this embodiment are the same as those of the foregoing [Embodiment 1] except at least a portion of the driving electrode 310 exposed so as to form a geometrical pattern such as a rectangular ring, a specific character or a trade mark when it is viewed from above.

In the fingerprint sensor package according to this embodiment, an area corresponding to the black coating layer 520 and the second protective layer 510 placed above the at least a portion of the driving electrode 310 is opened, and thus the predetermined area of the driving electrode 310 forms various geometrical patterns such as a rectangular ring shown in FIG. 6 when the package is viewed from above.

Further, the certain area of the driving electrode 310, which is exposed as the black coating layer 520 and the second protective layer 510 are opened, may form a name of a manufacturer or a specific trademark or shape.

The present invention is not limited to the foregoing embodiments, and may be changed and modified in various forms without departing from the scope of the invention.

Therefore, the foregoing embodiments are provided for illustrative purposes only and are not intended to limit the scope of the invention, and it will be appreciated by those skilled in the art that changes may be made in these embodiments without departing from the principles and spirit of the invention, the scope of which is defined in the appended claims and their equivalents.

### INDUSTRIAL APPLICABILITY

The present invention is effectively applicable to various devices such as a mobile device or a computer required to have an authentication function based on fingerprint recognition and a pointing function based on fingerprint recognition and thus has high industrial applicability, since fingerprint image data can be accurately obtained by minimizing a distance between a top surface of a sensing portion in a fingerprint sensor and a fingerprint, and mechanical strength and tolerance to electrostatic discharge are improved as compared with the existing fingerprint sensor packages.

1. A fingerprint sensor package comprising:
a fingerprint sensor which comprises a sensing portion for sensing fingerprint data;
via frame being arranged around and spaced apart from the fingerprint sensor and comprising via holes;
a conductive pattern which comprises a connection electrode by which a bonding pad provided on an upper surface of the fingerprint sensor and used for external access and the via hole of the via frame are electrically connected, and a driving electrode which is insulated from the connection electrode and generates a driving signal for the fingerprint sensor;
a mold body in which the fingerprint sensor and the via frame are integrated; and
a protective layer covering the upper surface of the fingerprint sensor.

2. The fingerprint sensor package according to claim 1, wherein a solder land is exposed to an outside of the mold body at an opposite side to a portion of the via hole to be electrically connected to the bonding pad of the fingerprint sensor by the connection electrode.

3. The fingerprint sensor package according to claim 1, wherein the protective layer comprises:
a first protective layer formed on an entire area of an upper surface except the conductive pattern;
a second protective layer formed on an entire area of an upper surface covering the first protective layer and the conductive pattern; and
a coating layer formed on an entire area of an upper surface of the second protective layer and having black, white or another color.

4. The fingerprint sensor package according to claim 1, wherein a plurality of compensation holes is formed in an outward area around the via holes electrically connected to the bonding pad of the fingerprint sensor on the via frame, and prevents the fingerprint sensor package from warpage due to difference in a coefficient of thermal expansion between the mold resin for integrating the fingerprint sensor with the via frame and the conductive pattern formed on the upper surface of the via frame.

5. The fingerprint sensor package according to claim 3, wherein area corresponding to the coating layer and the second protective layer placed above a predetermined area of the driving electrode is opened to expose the predetermined area of the driving electrode.

6. A method of manufacturing a fingerprint sensor package, the method comprising:
preparing a via frame comprising conductive via holes and a hollow;
molding a die and the via frame to be integrated by a mold resin in a state that the die is placed in the hollow of the via frame;
forming a first protective layer on an entire area on a side, in which a bonding pad is formed, of a structure comprising the molded die;
selectively removing a predetermined area of the first protective layer;
forming a conductive patter which comprises a connection electrode for connecting the bonding pad and the via hole of the die on the first protective layer, and a driving electrode for generating a driving signal for a fingerprint sensor;
forming a second protective layer on an entire area of an upper surface in a structure comprising the conductive pattern; and
forming a coating layer having black, white or another color on the second protective layer.

7. A method of manufacturing a fingerprint sensor package, the method comprising:
preparing a via frame comprising conductive via holes and a hollow;
attaching a molding tape for die attach and die molding to cover the hollow of the via frame;
attaching a die to a center portion of the molding tape so that a bonding pad of the die can face the molding tape;
molding the die and the via frame to be integrated by a mold resin (an epoxy molding compound (EMC));
removing the molding tape;
forming a first protective layer on an upper surface, from which the molding tape is removed, of a structure comprising the molded die, without forming the first protective layer in an area above the via hole and an area corresponding to the bonding pad;
forming a connection electrode for connecting the bonding pad and the via hole of the die on the first protective layer, and a driving electrode for generating a driving signal for a fingerprint sensor;
forming a second protective layer on an entire area of an upper surface in a structure comprising the conductive pattern; and
forming a coating layer having black, white or another color on the second protective layer.

8. The method according to claim 6, further comprising exposing a solder land for mounting to a main board through laser drilling.

9. The method according to claim 6, further comprising forming a plurality of compensation holes placed in an outward area around the via holes electrically connected to the bonding pad of the fingerprint sensor on the via frame, and preventing the fingerprint sensor package from warpage due to difference in a coefficient of thermal expansion between the mold resin for integrating the fingerprint sensor with the via frame and the conductive pattern formed on the upper surface of the via frame.

10. The method according to claim 6, further comprising opening area corresponding to the coating layer and the second protective layer placed above a predetermined area of the driving electrode to expose the predetermined area of the driving electrode.

11. The method according to claim 7, further comprising exposing a solder land for mounting to a main board through laser drilling.

12. The method according to claim 7, further comprising forming a plurality of compensation holes placed in an outward area around the via holes electrically connected to the bonding pad of the fingerprint sensor on the via frame, and preventing the fingerprint sensor package from warpage due to difference in a coefficient of thermal expansion between the mold resin for integrating the fingerprint sensor with the via frame and the conductive pattern formed on the upper surface of the via frame.

13. The method according to claim 7, further comprising opening area corresponding to the coating layer and the second protective layer placed above a predetermined area of the driving electrode to expose the predetermined area of the driving electrode.
